(19) United States
(12) Patent Application Publication
(10) Pub. No.: US 2026/0173268 A1
(43) Pub. Date: Jun. 18, 2026

(54) Multilayer Circuit Board and Electronic Device Using Same

(71) Applicant: AAC Microtech (Changzhou) Co., Ltd., Changzhou City (CN)

(72) Inventor: Guohui Chen, Changzhou (CN)

(21) Appl. No.: 19/278,761

(22) Filed: Jul. 23, 2025

Related U.S. Application Data
(63) Continuation of application No. PCT/CN2024/139679, filed on Dec. 16, 2024.

(51) Int. Cl. H05K 1/11

(52) U.S. Cl. CPC H05K 1/115; H05K 2201/05; H05K 2201/093; H05K 2201/09618

(57) ABSTRACT

The present application provides a multilayer circuit board and an electronic device. The multilayer circuit board has a circuit unit layer having at least two parallel and spaced circuit layers and an insulation layer disposed between adjacent circuit layers. A conductive through hole penetrating through the thickness direction is formed in the circuit unit layer, the conductive through hole is formed by being surrounded by an inner wall. The multilayer circuit board of the present application realizes parallel connection between the circuit layers, effectively controls the resistance value of the circuit board, and meets performance requirements while reducing the overall thickness of the multilayer circuit board and lowering the space requirement for mounting the multilayer circuit board.

### TECHNICAL FIELD

The present application is in the field of circuit board technology, specifically relating to a multilayer circuit board and an electronic device using such a multilayer circuit board.

### BACKGROUND

With the rapid development of electronic products, different electronic products have different resistance values, and in circuit design, some electronic products have requirements for resistance value limitation. In related electronic products, to reduce the circuit resistance of circuit boards, methods such as reducing circuit line length, increasing conductor thickness, and increasing conductor line width can usually be adopted to reduce conductor resistance. However, due to the space limitations of electronic product mounting structures, it is not possible to reduce resistance by increasing conductor thickness.

Therefore, it is necessary to provide a multilayer circuit board and an electronic device that can meet both mounting space and resistance performance requirements.

### SUMMARY

The object of the present application is to provide a multilayer circuit board with reduced thickness that can meet product structural space requirements while effectively controlling resistance value and conforming to the resistance performance requirements of electronic products.

To achieve the above purposes, the present invention provides a multilayer circuit board, comprising a circuit unit layer which comprises at least two parallel and spaced circuit layers and an insulation layer disposed between adjacent circuit layers. Surfaces oppositely arranged along a thickness direction of the circuit unit layer are defined as a first side surface and a second side surface. A conductive through hole penetrating through the thickness direction is formed in the circuit unit layer, the conductive through hole is formed by being surrounded by an inner wall, a first copper plating layer is provided only on the first side surface or the second side surface, a second copper plating layer connected to the first copper plating layer is plated on the inner wall, and at least two circuit layers achieve parallel electrical connection through the second copper plating layer.

Further, an end of the second copper plating layer away from the first copper plating layer aligns with one of the first side surface and the second side surface where the first copper plating layer is not provided.

Further, the circuit unit layer further comprises an outer wall oppositely arranged with the inner wall, and the first copper plating layer extends to be aligned with the outer wall.

Further, the conductive through hole comprises a plurality of conductive through holes, and the plurality of conductive through holes are spaced apart.

Further, the circuit unit layer comprises three parallel and spaced circuit layers and two insulation layers respectively disposed between adjacent circuit layers.

Further, the three circuit layers have consistent line lengths, and the three circuit layers are connected in parallel through the second copper plating layer in the conductive through hole.

Further, the three circuit layers have inconsistent line lengths, and the three circuit layers are connected in parallel through the second copper plating layer in the conductive through hole.

Further, the conductive through hole is a cylindrical hole.

Further, the multilayer circuit board is one of a flexible circuit board, a rigid circuit board, or a rigid-flex circuit board.

Further, the present invention also provides an electronic device, comprising a multilayer circuit board as described above.

The multilayer circuit board of the present application comprises a first copper plating layer provided on the first side surface or second side surface of the circuit unit layer, and a second copper plating layer provided on the inner wall of the conductive through hole; the second copper plating layer is connected to the first copper plating layer.

In this structure of the multilayer circuit board, the first copper plating layer is plated only on one side surface of the circuit unit layer, while the other side of the circuit unit layer has no copper plating layer. In the thickness direction, only one side of the circuit unit layer is thickened, which realizes parallel connection between circuit layers, effectively controls the resistance value of the circuit board, and meets performance requirements while reducing the overall thickness of the multilayer circuit board and lowering the space requirement for mounting the multilayer circuit board; the first copper plating layer forms a protective layer for the circuit layers and to some extent increases the conductor thickness, reducing the resistance value of the multilayer circuit board.

### BRIEF DESCRIPTION OF THE DRAWINGS

In order to more clearly explain the technical solutions in the embodiments of the present application, the following will briefly introduce the drawings required in the embodiments or exemplary technical descriptions. Obviously, the drawings in the following description are only for the application. In some embodiments, for those of ordinary skill in the art, without paying any creative labor, other drawings may be obtained based on these drawings, in which:

FIG. 1 is a cross-sectional view of a multilayer circuit board in accordance with an embodiment of the present application.

FIG. 2 is a structural view of a surface of the multilayer circuit board with a first copper plating layer thereof removed.

FIG. 3 is another structural view of a surface of the multilayer circuit board without the first copper plating layer.

### DETAILED DESCRIPTION OF THE EMBODIMENTS

The following will be taken in conjunction with the accompanying drawings of embodiments of the present invention, The technical scheme in the embodiments of the invention is clearly and completely described, Obviously, the described embodiments are merely part of the embodiments of the present invention, and not all embodiments are based on the embodiments of the present invention, and all other embodiments attained by those of ordinary skill in the art without inventive effort are within the scope of the present invention.

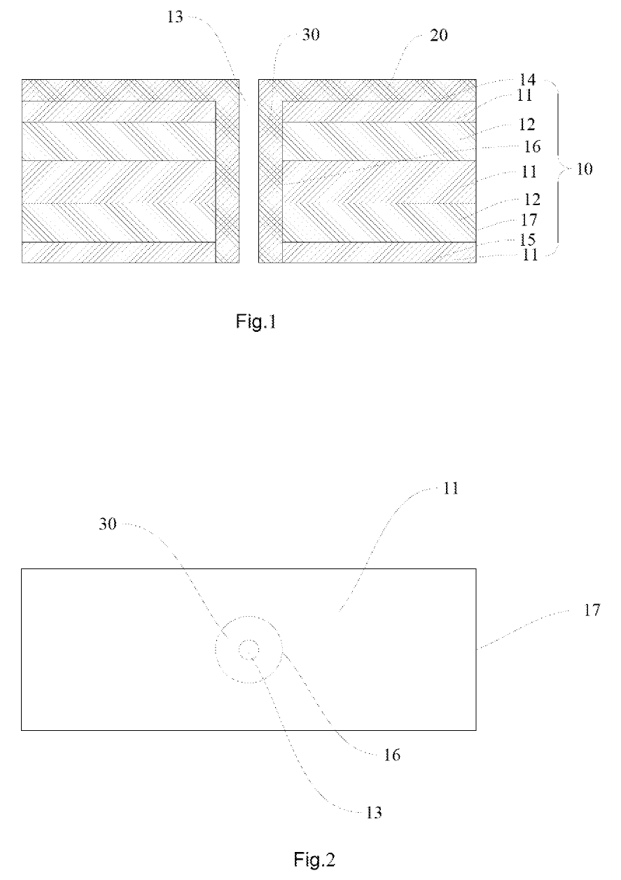

In a first aspect, referring to FIGS. 1 to 3, the present application provides a multilayer circuit board comprising a circuit unit layer 10; the circuit unit layer 10 comprises at least two parallel and spaced circuit layers 11 and an insulation layer 12 disposed between adjacent circuit layers 11; surfaces oppositely arranged along a thickness direction of the circuit unit layer 10 are a first side surface 14 and a second side surface 15; a conductive through hole 13 penetrating through the thickness direction is formed in the circuit unit layer 10, the conductive through hole 13 is formed by being surrounded by an inner wall 16, a first copper plating layer 20 is provided only on the first side surface 14 or the second side surface 15, a second copper plating layer 30 connected to the first copper plating layer 20 is plated on the inner wall 16, and at least two circuit layers 11 achieve parallel connection through the second copper plating layer 30. That is, the circuit unit layer 10 is formed by stacking the insulation layer 12 and the circuit layer 11 alternately to form two oppositely arranged surfaces, with the first copper plating layer 20 provided on one side surface.

The multilayer circuit board of the present application comprises a first copper plating layer 20 provided on the first side surface 14 or second side surface 15 of the circuit unit layer 10, and a second copper plating layer 30 provided on the inner wall 16 of the conductive through hole 13; the second copper plating layer 30 is connected to the first copper plating layer 20. In this structure of the multilayer circuit board, the first copper plating layer 20 is plated only on one side surface of the circuit unit layer 10, while the other side of the circuit unit layer 10 has no first copper plating layer 20. In the thickness direction, only one side of the circuit unit layer 10 is thickened, which realizes parallel connection between circuit layers 11, effectively controls the resistance value of the circuit board, and meets performance requirements while reducing the overall thickness of the multilayer circuit board and lowering the space requirement for mounting the multilayer circuit board; the first copper plating layer 20 forms a protective layer for the circuit layers 11 and to some extent increases the conductor thickness, reducing the resistance value of the multilayer circuit board.

Optionally, an end of the second copper plating layer 30 away from the first copper plating layer 20 aligns with the surface where the first copper plating layer 20 is not provided.

Optionally, the circuit unit layer 10 further comprises an outer wall 17 oppositely arranged with the inner wall 16, and the first copper plating layer 20 extends to be aligned with the outer wall 17.

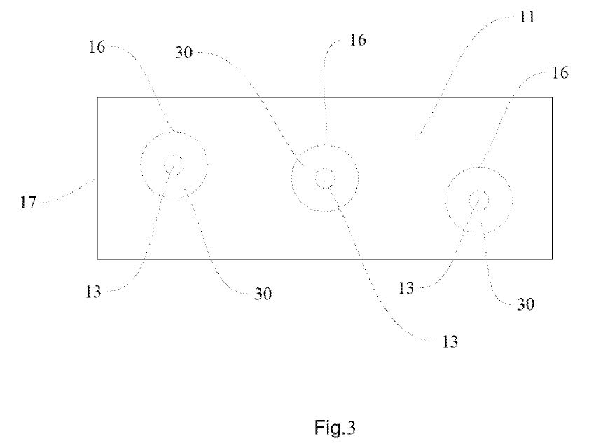

Referring to FIG. 3, optionally, the conductive through hole 13 comprises a plurality of conductive through holes that are spaced apart. The conductive through hole 13 is used to enable parallel connection between the circuit layers 11. The more conductive through holes 13 are provided, the greater the reduction in resistance, which can further effectively control the resistance value of the multilayer circuit board. It can be understood that the number of conductive through holes 13 can be specifically set according to actual performance requirements.

Optionally, the circuit layer 11 is made of copper material; the insulation layer 12 is made of a composite material of insulating material and adhesive.

Optionally, the insulating material includes one or more of insulating ink, polyimide, or polyethylene naphthalate.

Referring to FIG. 1, in a specific embodiment of the present application, the circuit unit layer 10 comprises three parallel and spaced circuit layers 11 and two insulation layers 12 respectively disposed between adjacent circuit layers 11; the circuit layers 11 and insulation layers 12 are stacked alternately, with the insulation layers 12 sandwiched between the circuit layers 11; the conductive through hole 13 penetrates through the circuit unit layer 10 in the thickness direction.

The three parallel circuit layers 11 are connected in parallel at both ends through the conductive through hole 13, thereby effectively controlling the circuit resistance value and reducing circuit working heat exceeding the standard; no copper plating layer is provided on the other side surface of the circuit unit layer 10, reducing the overall thickness of the multilayer circuit board and reducing the required mounting space.

Optionally, the insulation layer 12 may be a single-layer structure made of insulating material and adhesive composite material, or a multi-layer structure formed by stacking multiple single-layer structures made of insulating material and adhesive composite material; of course, the circuit layer 11 is not limited to a single-layer structure; the parallel design between circuit layers 11 can be adjusted through different circuit layer 11 arrangements.

Optionally, the three circuit layers have consistent line lengths, and the three circuit layers are connected in parallel through the second copper plating layer in the conductive through hole.

Optionally, the three circuit layers have inconsistent line lengths, and the three circuit layers are connected in parallel through the second copper plating layer in the conductive through hole.

Optionally, referring to FIGS. 2 and 3, the conductive through hole 13 is a cylindrical hole, that is, the cross-section of the conductive through hole 13 is circular.

Optionally, the multilayer circuit board may be a Flexible Printed Circuit (FPC), a Printed Circuit Board (PCB), or a Rigid-Flex Printed Circuit Board (R-FPCB).

In a second aspect, the present application provides an electronic device comprising the above-mentioned multilayer circuit board. The electronic device includes a Voice Coil Motor (VCM).

The foregoing is merely illustrative of embodiments of the present invention, and it should be noted that modifications may be made to those skilled in the art without departing from the spirit of the invention but are intended to be within the scope of the inventio.

What is claimed is:

1. A multilayer circuit board, comprising a circuit unit layer which comprises at least two parallel and spaced circuit layers and an insulation layer disposed between adjacent circuit layers; wherein
surfaces oppositely arranged along a thickness direction of the circuit unit layer are defined as a first side surface and a second side surface;
a conductive through hole penetrating through the thickness direction is formed in the circuit unit layer, the conductive through hole is formed by being surrounded by an inner wall, a first copper plating layer is provided only on the first side surface or the second side surface, a second copper plating layer connected to the first copper plating layer is plated on the inner wall, and at least two circuit layers achieve parallel electrical connection through the second copper plating layer.

2. The multilayer circuit board as described in claim 1, wherein an end of the second copper plating layer away from the first copper plating layer aligns with one of the first side surface and the second side surface where the first copper plating layer is not provided.

3. The multilayer circuit board as described in claim 1, wherein the circuit unit layer further comprises an outer wall oppositely arranged with the inner wall, and the first copper plating layer extends to be aligned with the outer wall.

4. The multilayer circuit board as described in claim 1, wherein the conductive through hole comprises a plurality of conductive through holes, and the plurality of conductive through holes are spaced apart.

5. The multilayer circuit board as described in claim 1, wherein the circuit unit layer comprises three parallel and spaced circuit layers and two insulation layers respectively disposed between adjacent circuit layers.

6. The multilayer circuit board as described in claim 5, wherein the three circuit layers have consistent line lengths, and the three circuit layers are connected in parallel through the second copper plating layer in the conductive through hole.

7. The multilayer circuit board as described in claim 5, wherein the three circuit layers have inconsistent line lengths, and the three circuit layers are connected in parallel through the second copper plating layer in the conductive through hole.

8. The multilayer circuit board as described in claim 1, wherein the conductive through hole is a cylindrical hole.

9. The multilayer circuit board as described in claim 3, wherein the multilayer circuit board is one of a flexible circuit board, a rigid circuit board, or a rigid-flex circuit board.

10. An electronic device, comprising a multilayer circuit board as described in claim 1.
